(19) United States
(12) Patent Application Publication
(10) Pub. No.: US 2026/0068146 A1
(43) Pub. Date: Mar. 5, 2026

(54) INTEGRATED CIRCUIT DEVICE

(71) Applicant: Samsung Electronics Co., Ltd., Suwon-si (KR)

(72) Inventors: Kangin Kim, Suwon-si (KR); Kyounghwan Kim, Suwon-si (KR)

(21) Appl. No.: 19/273,621

(22) Filed: Jul. 18, 2025

(30) Foreign Application Priority Data
Sep. 3, 2024 (KR) 10-2024-0119566

(51) Int. Cl. H10B 12/00

(52) U.S. Cl. CPC H10B 12/50; H10B 12/09; H10B 12/34

(57) ABSTRACT

The technical idea of the inventive concept provides an integrated circuit device including a substrate including a cell array area and a boundary area adjacent the cell array area, a plurality of word lines extending in a first horizontal direction and alternately arranged in a second horizontal direction, in the cell array area and the boundary area, and a plurality of word line contacts in contact with respective ones of the plurality of word lines in the boundary area. The plurality of word lines include a plurality of first word and a plurality of second word lines alternately arranged in the second horizontal direction, a width of each of the plurality of first word lines in the second horizontal direction differs from a width of each of the plurality of second word lines in the second horizontal direction.

### CROSS-REFERENCE TO RELATED APPLICATION

This application is based on and claims priority under 35 U.S.C. § 119 to Korean Patent Application No. 10-2024-0119566, filed on Sep. 3, 2024, in the Korean Intellectual Property Office, the disclosure of which is incorporated by reference herein in its entirety.

### BACKGROUND

The inventive concept relates to an integrated circuit device, and particularly, to an integrated circuit device having word lines buried in a substrate.

Recently, along with a gradual increase in the integration of integrated circuit devices, the structure of an integrated circuit device having a buried channel array transistor (BCAT) in a form in which a plurality of word lines are buried in a substrate has been proposed. Accordingly, various studies for improving and stabilizing an operation and the reliability of a BCAT have been conducted.

### SUMMARY

The inventive concept provides an integrated circuit device in which a plurality of word lines each having a width gradually increasing or decreasing away from a cell array area are alternately arranged.

The problems to be solved by the technical idea of the inventive concept are not limited to the problem mentioned above, and other problems which are not mentioned could be clearly understood by those of ordinary skill in the art from the description below.

According to some embodiments of the inventive concept, there is provided an integrated circuit device including a substrate including a cell array area including a plurality of active areas and a boundary area including a plurality of dummy active areas and adjacent the cell array area, a plurality of word lines extending in a first horizontal direction and alternately arranged in a second horizontal direction, the plurality of word lines extend in the cell array area and the boundary area, and a plurality of word line contacts in contact with respective ones of the plurality of word lines in the boundary area. The plurality of word lines include a plurality of first word lines and a plurality of second word lines alternately arranged in the second horizontal direction, a width of each of the plurality of first word lines in the second horizontal direction differs from a width of each of the plurality of second word lines in the second horizontal direction.

According to some embodiments of the inventive concept, there is provided an integrated circuit device including a substrate including a cell array area including a plurality of active areas and a boundary area including a plurality of dummy active areas and adjacent the cell array area, a plurality of word lines extending in a first horizontal direction and alternately arranged in a second horizontal direction, the plurality of word lines extend in the cell array area and the boundary area, and a plurality of word line contacts in contact with respective ones of the plurality of word lines in the boundary area. The plurality of word lines include a plurality of first word lines having a width gradually increasing in the second horizontal direction away from the cell array area extending into the boundary area, and a plurality of second word lines alternately arranged with the plurality of first word lines in the second horizontal direction and having a constant width in the second horizontal direction.

According to some embodiments of the inventive concept, there is provided an integrated circuit device including a substrate including a cell array area including a plurality of active areas and a boundary area including a plurality of dummy active areas and adjacent the cell array area, a plurality of word lines including a plurality of first word lines and a plurality of second word lines extending in a first horizontal direction and alternately arranged in a second horizontal direction, the plurality of word lines extend in the cell array area and the boundary area, and a plurality of word line contacts in contact with respective ones of the plurality of first word lines in a vertical direction in the boundary area. Each of the plurality of first word lines includes a first portion in the boundary area, a second portion extending from the cell array area into the boundary area, and a third portion between the first portion and the second portion, each of the plurality of second word lines includes a fourth portion in the boundary area and a fifth portion extending from the cell array area into the boundary area and in contact with the fourth portion, a first width of the first portion of each of the plurality of first word lines in the second horizontal direction is greater than a second width of the second portion of the first word line in the second horizontal direction, and a fourth width of the fourth portion of each of the plurality of second word lines in the second horizontal direction is less than a fifth width of the fifth portion of a second word line of the plurality of second word lines in the second horizontal direction.

### BRIEF DESCRIPTION OF THE DRAWINGS

Embodiments of the inventive concept will be more clearly understood from the following detailed description taken in conjunction with the accompanying drawings in which:

FIG. 1 is a layout diagram illustrating a schematic structure of an integrated circuit device according to embodiments;

FIG. 2 is an enlarged layout diagram of an area EX1 of FIG. 1;

FIG. 3 is a cross-sectional view taken along line X1-X1′ of FIG. 2;

FIG. 4A is a cross-sectional view taken along line Y1-Y1′ of FIG. 2;

FIG. 4B is a cross-sectional view taken along line Y2-Y2′ of FIG. 2;

FIG. 5 is an enlarged layout diagram of an area EX2 of FIG. 2;

FIG. 6 is a layout diagram illustrating a schematic structure of an integrated circuit device according to embodiments, and illustrates a portion corresponding to FIG. 2;

FIG. 7 is an enlarged layout diagram of an area EX3 of FIG. 6; and

FIGS. 8, 9A, 9B, 9C, 10A, 10B, 11A, 11B, and 11C illustrate a method of manufacturing an integrated circuit device, according to embodiments, wherein FIGS. 8, 9A, 10A, and 11A are cross-sectional views taken along the line Y1-Y1′ of FIG. 2, FIGS. 9B, 10B, and 11B are cross-sectional views taken along the line Y2-Y2′ of FIG. 2, FIG. 9C is an enlarged layout diagram of the area EX2 of FIG. 2, and FIG. 11C is a cross-sectional view taken along the line X1-X1′ of FIG. 2.

### DETAILED DESCRIPTION OF THE EMBODIMENTS

Hereinafter, embodiments are described in detail with reference to the accompanying drawings. Like reference numerals in the drawings denote like elements, and thus their repetitive description will be omitted.

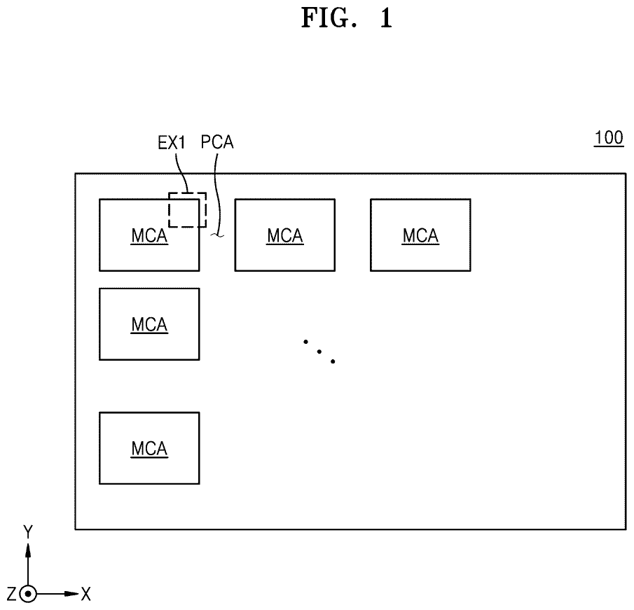

FIG. 1 is a layout diagram illustrating a schematic structure of an integrated circuit device 100 according to embodiments.

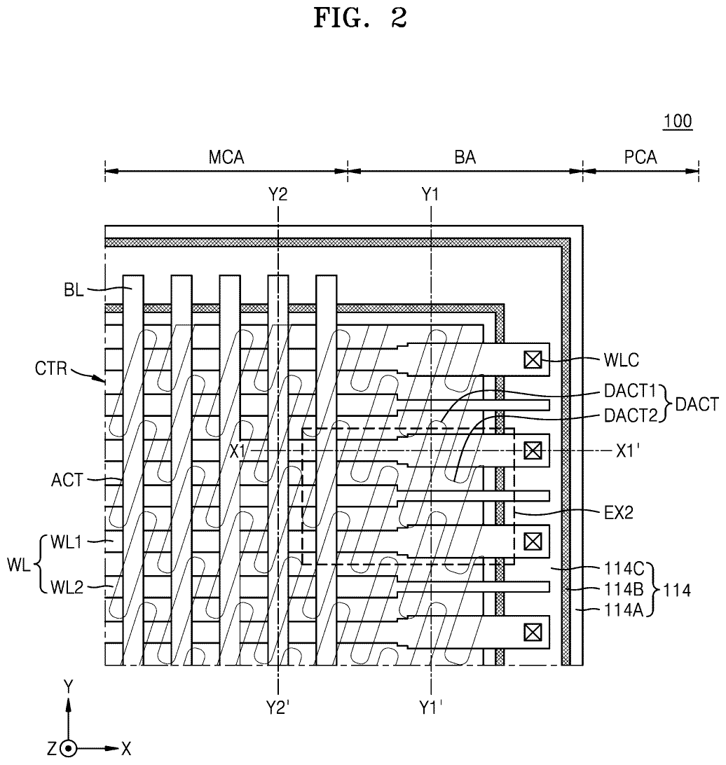

FIG. 2 is an enlarged layout diagram of an area EX1 of FIG. 1.

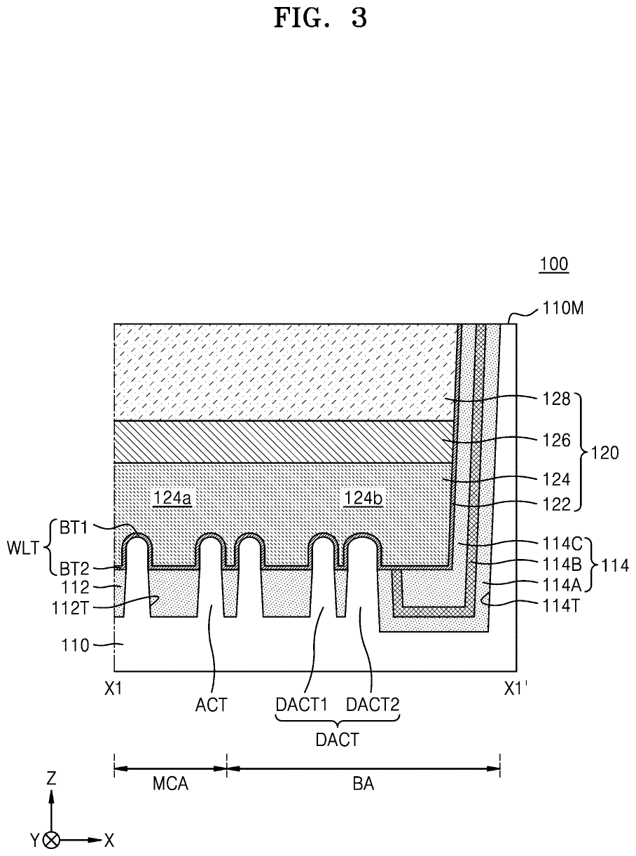

FIG. 3 is a cross-sectional view taken along line X1-X1′ of FIG. 2.

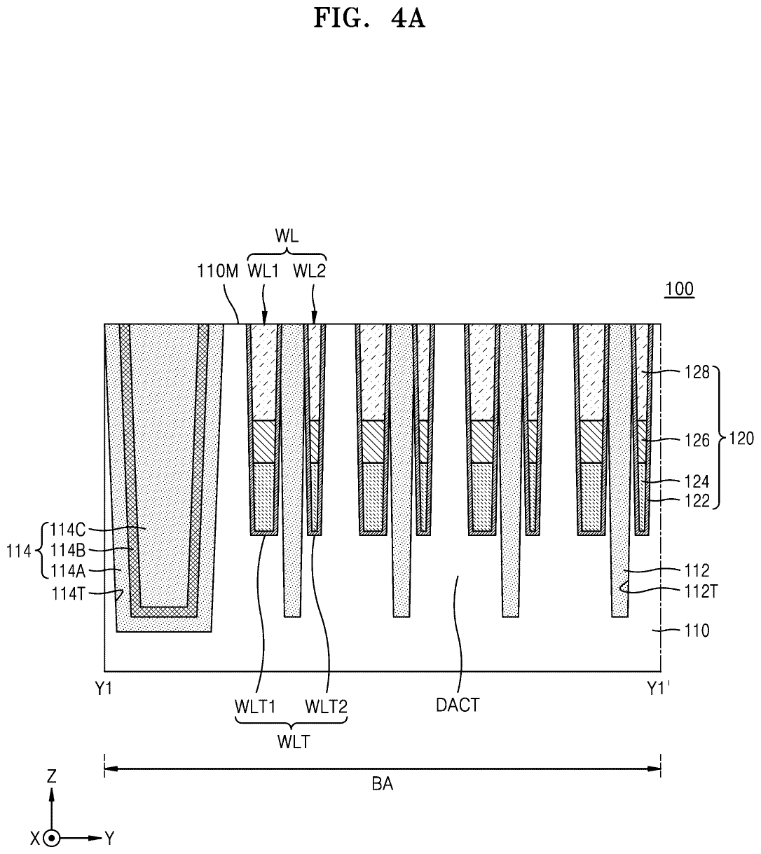

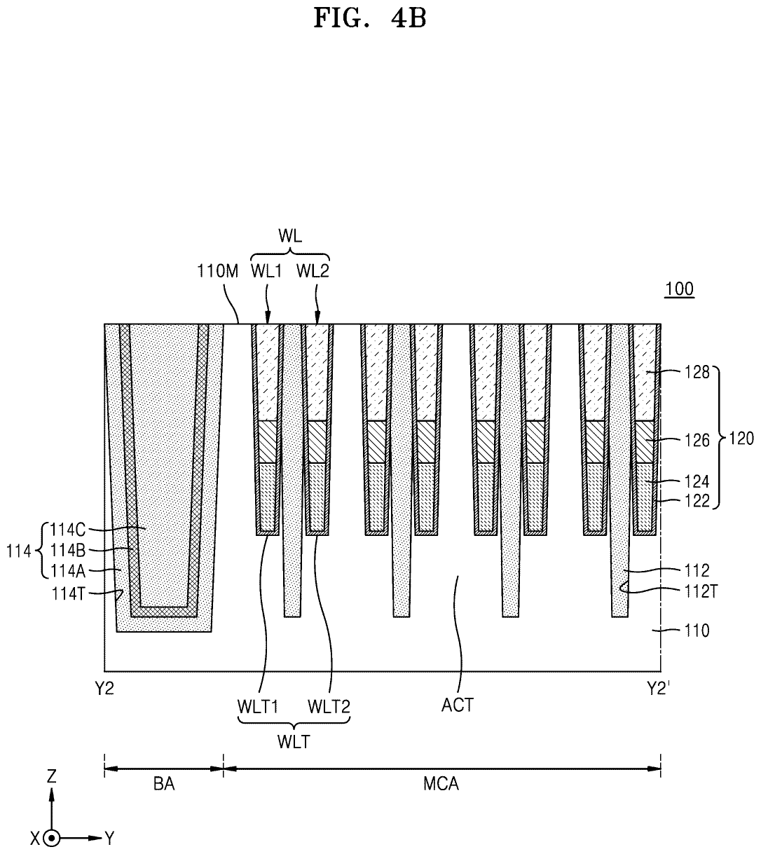

FIG. 4A is a cross-sectional view taken along line Y1-Y1′ of FIG. 2.

FIG. 4B is a cross-sectional view taken along line Y2-Y2′ of FIG. 2.

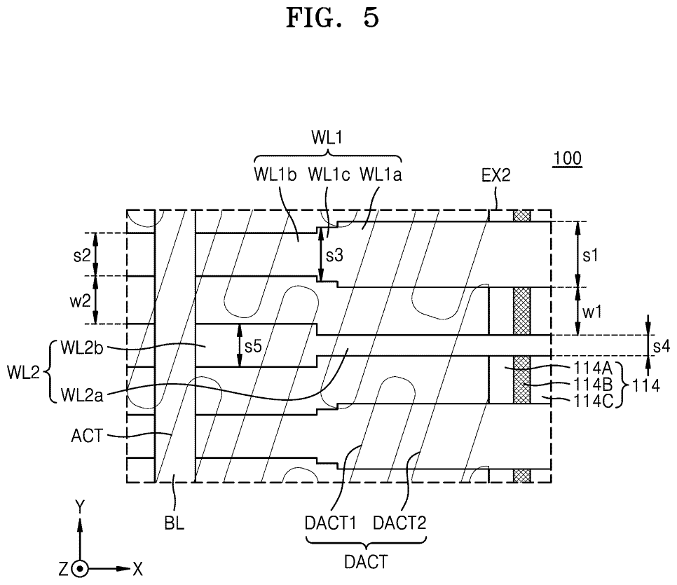

FIG. 5 is an enlarged layout diagram of an area EX2 of FIG. 2.

Referring to FIGS. 1 to 5, the integrated circuit device 100, according to some embodiments, may include a substrate 110 including a cell array area MCA, a peripheral circuit area PCA, and a boundary area BA between the cell array area MCA and the peripheral circuit area PCA.

In embodiments, the cell array area MCA may be a cell array area of a dynamic random access memory (DRAM) device, and the peripheral circuit area PCA may be a core area or a peripheral circuit area of the DRAM device. For example, the cell array area MCA may include a cell transistor CTR and a capacitor structure (not shown) connected to the cell transistor CTR.

In embodiments, the peripheral circuit area PCA may include a peripheral circuit transistor (not shown) configured to transmit a signal and/or power to the cell transistor CTR included in the cell array area MCA. In embodiments, the peripheral circuit transistor (not shown) may include various circuits, such as a command decoder, a control logic, an address buffer, a row decoder, a column decoder, a sense amplifier, and a data input-output circuit.

In embodiments, the peripheral circuit area PCA may indicate an area between two adjacent cell array areas MCA. For example, the cell array area MCA may be spaced apart from the peripheral circuit area PCA with the boundary area BA therebetween.

In embodiments, a device isolation trench 112T may be formed in the substrate 110, and a device isolation layer 112 may be arranged inside the device isolation trench 112T. The device isolation trench 112T may be partially or completely filled with the device isolation layer 112.

In embodiments, in the cell array area MCA, a plurality of active areas ACT may be defined in the substrate 110 by the device isolation layer 112. In embodiments, in the cell array area MCA, the plurality of active areas ACT may have a long axis in a diagonal direction with respect to a first horizontal direction (the X direction) and a second horizontal direction (the Y direction) intersecting with the first horizontal direction (the X direction). In embodiments, the plurality of active areas ACT may be spaced apart from each other in the first horizontal direction (the X direction) and the second horizontal direction (the Y direction).

In embodiments, in the boundary area BA, a plurality of dummy active areas DACT may be defined in the substrate 110 by the device isolation layer 112. In embodiments, in a plan view, the plurality of dummy active areas DACT may surround the plurality of active areas ACT in the cell array area MCA and spaced apart from the plurality of active areas ACT.

In embodiments, the plurality of dummy active areas DACT may be arranged in the second horizontal direction (the Y direction) at both sides of the cell array area MCA in the first horizontal direction (the X direction). For example, the plurality of dummy active areas DACT may surround both the sides of the cell array area MCA in the first horizontal direction (the X direction) in the boundary area BA.

In some embodiments, the plurality of dummy active areas DACT may be arranged along the periphery of the cell array area MCA. For example, the plurality of dummy active areas DACT may surround the four sides of the cell array area MCA. For example, the plurality of dummy active areas DACT may be arranged in the first horizontal direction (the X direction) and surround both the sides of the cell array area MCA in the second horizontal direction (the Y direction), and be arranged in the second horizontal direction (the Y direction) and surround both the sides of the cell array area MCA in the first horizontal direction (the X direction).

In embodiments, a dummy active area DACT may include a first dummy active area DACT1 and a second dummy active area DACT2. A first dummy active area DACT1 selected from among the plurality of dummy active areas DACT may be adjacent to the plurality of active areas ACT, and a second dummy active area DACT2 selected from among the plurality of dummy active areas DACT may be spaced apart from the plurality of active areas ACT in the first horizontal direction (the X direction) with the first dummy active area DACT1 therebetween.

In embodiments, a plurality of second dummy active areas DACT2 may be at the outermost among the plurality of dummy active areas DACT. For example, the plurality of second dummy active areas DACT2 may be most adjacent to the peripheral circuit area PCA among the plurality of dummy active areas DACT and be between the peripheral circuit area PCA and a plurality of first dummy active areas DACT1.

Although FIG. 2 shows that the plurality of second dummy active areas DACT2 are arranged in a column in the second horizontal direction (the Y direction), the plurality of second dummy active areas DACT2 are not limited thereto. For example, the plurality of second dummy active areas DACT2 may be arranged in two or more columns in the second horizontal direction (the Y direction). For example, the plurality of second dummy active areas DACT2 may be arranged in two or more rows/columns in the second horizontal direction (the Y direction) and the first horizontal direction (the X direction) and surround the plurality of active areas ACT and the plurality of first dummy active areas DACT1.

In embodiments, the plurality of first dummy active areas DACT1 may have a uniform horizontal width. For example, the plurality of first dummy active areas DACT1 may have a long axis extending in a diagonal direction with respect to the first horizontal direction (the X direction) and the second horizontal direction (the Y direction). For example, the width of each of the plurality of first dummy active areas DACT1 in the first horizontal direction (the X direction) may be similar to or the same as the width of each of the plurality of active areas ACT in the first horizontal direction (the X direction).

In embodiments, the plurality of second dummy active areas DACT2 may have a uniform horizontal width. For example, the plurality of second dummy active areas DACT2 may have a long axis extending in a diagonal direction with respect to the first horizontal direction (the X direction) and the second horizontal direction (the Y direction). In this case, the area of each of the plurality of second dummy active areas DACT2 may be greater than the area of each of the plurality of first dummy active areas DACT1. For example, the width of each of the plurality of second dummy active areas DACT2 in the first horizontal direction (the X direction) may be greater than the width of each of the plurality of first dummy active areas DACT1 in the first horizontal direction (the X direction).

In embodiments, the device isolation layer 112 may surround the plurality of active areas ACT and the plurality of dummy active areas DACT on the substrate 110. The bottom level of the device isolation trench 112T may be various according to the width of the device isolation trench 112T in a horizontal direction. For example, the greater the width of the device isolation trench 112T in the horizontal direction, the lower the vertical level of the bottom surface of the device isolation trench 112T. The term “vertical level” used in the specification indicates a height from a main surface 110M of the substrate 110 in the vertical direction (the Z direction or the −Z direction).

In embodiments, the substrate 110 may include silicon, e.g., monocrystalline silicon, polycrystalline silicon, or amorphous silicon. In some embodiments, the substrate 110 may include at least one selected from among germanium (Ge), silicon germanium (SiGe), silicon carbide (SiC), gallium arsenide (GaAs), indium arsenide (InAs), and/or indium phosphide (InP). In some embodiments, the substrate 110 may include a conductive area, e.g., an impurity-doped well or an impurity-doped structure. In embodiments, the device isolation layer 112 may include an oxide film, a nitride film, or a combination thereof.

In embodiments, in the boundary area BA, a boundary structure 114 surrounding the plurality of active areas ACT and the plurality of dummy active areas DACT may be arranged. In embodiments, the plurality of active areas ACT may be spaced apart from the boundary structure 114 with the plurality of dummy active areas DACT therebetween. For example, the plurality of dummy active areas DACT may be between the plurality of active areas ACT and the boundary structure 114, thereby improving the uniformity of the plurality of active areas ACT in a process of manufacturing the integrated circuit device 100, and preventing a bending phenomenon of the plurality of active areas ACT having a fin structure.

In embodiments, a boundary trench 114T may be formed in the boundary area BA, and the boundary structure 114 may be inside the boundary trench 114T. In a plan view, the boundary structure 114 may surround the plurality of active areas ACT and the plurality of dummy active areas DACT. The boundary structure 114 may include a buried insulating layer 114A, an insulating liner 114B, and a gap-fill insulating layer 114C inside the boundary trench 114T.

The buried insulating layer 114A may be conformally on the inner wall of the boundary trench 114T. In some embodiments, the buried insulating layer 114A may include silicon oxide. The insulating liner 114B may be conformally on the buried insulating layer 114A on the inner wall of the boundary trench 114T. In some embodiments, the insulating liner 114B may include silicon nitride. The gap-fill insulating layer 114C may be on the insulating liner 114B and fill inside the boundary trench 114T. In embodiments, the gap-fill insulating layer 114C may include silicon oxide, such as tonen silazene (TOSZ), undoped silicate glass (USG), boro-phospho-silicate glass (BPSG), phosphosilicate glass (PSG), flowable oxide (FOX), plasma enhanced deposition of tetra-ethyl-ortho-silicate (PE-TEOS), or fluoride silicate glass (FSG).

In embodiments, a plurality of word lines WL may extend in the first horizontal direction (the X direction) across the plurality of active areas ACT and the plurality of dummy active areas DACT. For example, the plurality of word lines WL may be spaced apart from each other in the second horizontal direction (the Y direction) and extend to be parallel to each other. In embodiments, a plurality of bit lines BL on the plurality of word lines WL may extend in the second horizontal direction (the Y direction) to be parallel to each other. The plurality of bit lines BL may be electrically connected to the plurality of active areas ACT. For example, the plurality of bit lines BL may be connected to the plurality of active areas ACT via direct contacts (not shown). In embodiments, a capacitor structure (not shown) may be on the plurality of bit lines BL. In embodiments, the capacitor structure (not shown) may be connected to the plurality of active areas ACT via a contact structure (not shown) extending in the vertical direction (the Z direction) between the plurality of bit lines BL.

In embodiments, the plurality of word lines WL may include a plurality of first word lines WL1 and a plurality of second word lines WL2 alternately arranged in the second horizontal direction (the Y direction). In the cell array area MCA and the boundary area BA, the plurality of first word lines WL1 and the plurality of second word lines WL2 may extend in the first horizontal direction (the X direction) to be parallel to each other and may be alternately arranged in the second horizontal direction (the Y direction). In this case, in the boundary area BA, the width of each of the plurality of first word lines WL1 in the second horizontal direction (the Y direction) may be different from the width of each of the plurality of second word lines WL2 in the second horizontal direction (the Y direction).

In embodiments, each of the plurality of word lines WL may include a first portion WL1a or WL2a in the boundary area BA and a second portion WL1b or WL2b extending from the cell array area MCA to a portion of the boundary area BA and connected to the first portion WL1a or WL2a. In this case, the width of the first portion WL1a or WL2a of each of the plurality of word lines WL in the second horizontal direction (the Y direction) may be different from the width of the second portion WL1b or WL2b of each of the plurality of word lines WL in the second horizontal direction (the Y direction).

In embodiments, each of the plurality of first word lines WL1 may include the first portion WL1a and the second portion WL1b. Each of the plurality of second word lines WL2 may include the first portion WL2a and the second portion WL2b. The first portion WL1a of each of the plurality of first word lines WL1 may have a first width s1 in the second horizontal direction (the Y direction), and the first portion WL2a of each of the plurality of second word lines WL2 may have a fourth width s4 in the second horizontal direction (the Y direction). In this case, the first width s1 may be greater than the fourth width s4.

In embodiments, the first portion WL1a of the first word line WL1 may have the first width s1 in the second horizontal direction (the Y direction), and the second portion WL1b of the first word line WL1 may have a second width s2 in the second horizontal direction (the Y direction). In this case, the first width s1 may be greater than the second width s2. For example, the first width s1 may be greater by about 20% than the second width s2 but is not limited thereto.

In embodiments, each of the plurality of first word lines WL1 may further include a third portion WL1c. The third portion WL1c of the first word line WL1 may be between the first portion WL1a of the first word line WL1 and the second portion WL1b of the first word line WL1. In this case, the first portion WL1a, the second portion WL1b, and the third portion WL1c of the first word line WL1 may be consecutively and integrally formed. The third portion WL1c of the first word line WL1 may have a third width s3 in the second horizontal direction (the Y direction). In this case, the third width s3 may be greater than the second width s2 and less than the first width s1. By arranging the third portion WL1c between the first portion WL1a and the second portion WL1b, it may prevent the first word line WL1 from being cut at the interface between the first portion WL1a and the second portion WL1b due to a necking phenomenon. That is, in the boundary area BA, the plurality of first word lines WL1 may have a shape having a width in the second horizontal direction (the Y direction), which gradually increases away from the cell array area MCA in the first horizontal direction (the X direction). For example, each of the plurality of first word lines WL1 may have a stair shape. A step difference may be formed at the interface between the first portion WL1a and the third portion WL1c and the interface between the second portion WL1b and the third portion WL1c.

In embodiments, the first portion WL2a of the second word line WL2 may have the fourth width s4 in the second horizontal direction (the Y direction), and the second portion WL2b of the second word line WL2 may have a fifth width s5 in the second horizontal direction (the Y direction). In this case, the fourth width s4 may be less than the fifth width s5. For example, the fourth width s4 may be less by about 20% than the fifth width s5 but is not limited thereto. That is, in the boundary area BA, the plurality of second word lines WL2 may have a shape having a width in the second horizontal direction (the Y direction), which gradually decreases away from the cell array area MCA in the first horizontal direction (the X direction). For example, each of the plurality of second word lines WL2 may have a stair shape. A step difference may be formed at the interface between the first portion WL2a and the second portion WL2b.

In embodiments, the distance between the first word line WL1 and the second word line WL2 adjacent to each other in the second horizontal direction (the Y direction) may be constant. The first portion WL1a of the first word line WL1 may be spaced apart by a first distance w1 from the first portion WL2a of the second word line WL2 adjacent to the first word line WL1 in the second horizontal direction (the Y direction). The second portion WL1b of the first word line WL1 may be spaced apart by a second distance w2 from the second portion WL2b of the second word line WL2 adjacent to the first word line WL1 in the second horizontal direction (the Y direction). In this case, the first distance w1 may be the same as the second distance w2. To make the first distance w1 be the same as the second distance w2, the ratio of the first width s1 to the second width s2 may be the same as the ratio of the fifth width s5 to the fourth width s4. For example, the first width s1 may be greater by about 20% than the second width s2, and the fourth width s4 may be less by about 20% than the fifth width s5.

In embodiments, a plurality of word line contacts WLC may be in contact with some of the plurality of word lines WL in the boundary area BA. Particularly, the plurality of word line contacts WLC may be in contact with the first portions WL1a of the plurality of first word lines WL1 in the vertical direction (the Z direction), respectively.

In embodiments, the first portions WL1a and WL2a of the plurality of word lines WL may overlap the plurality of dummy active area DACT in the vertical direction (the Z direction). For example, each of the first portions WL1a and WL2a of the plurality of word lines WL may overlap three dummy active area DACT in the vertical direction (the Z direction) but is not limited thereto. Each of the first portions WL1a and WL2a of the plurality of word lines WL may overlap two or less or four or more dummy active areas DACT in the vertical direction (the Z direction) but is not limited thereto.

In embodiments, the integrated circuit device 100 according to the inventive concept may include the first word line WL1 having a width gradually increasing away from the cell array area MCA and the second word line WL2 having a width gradually decreasing away from the cell array area MCA. Accordingly, a discontinuity failure of a word line WL, which may occur in a processing process, may be prevented, thereby improving the reliability of the integrated circuit device 100. In addition, the width of the first portion WL1a of the first word line WL1 in the second horizontal direction (the Y direction), the first portion WL1a overlapping the dummy active area DACT in the vertical direction (the Z direction), may increase to prevent disconnection of a word line WL in the boundary area BA in a processing process, thereby improving the reliability of the integrated circuit device 100.

In embodiments, the substrate 110 may include a plurality of word line trenches WLT extending in the first horizontal direction (the X direction) to be parallel to each other, and a plurality of buried gate structures 120 may be inside the plurality of word line trenches WLT, respectively. The plurality of word line trenches WLT may extend from the cell array area MCA to the inside of the boundary area BA, and an end portion of each of the plurality of buried gate structures 120 may overlap each of the plurality of dummy active areas DACT and the boundary structure 114 in the vertical direction (the Z direction) in the boundary area BA.

In embodiments, each of the plurality of word line trenches WLT may include a first word trench line WLT1 and a second word trench line WLT2. In a plan view, the plurality of word line trenches WLT may have shapes corresponding to the plurality of word lines WL, respectively. For example, the first word trench line WLT1 may have the same shape as or a similar shape to that of the first word line WL1. The second word trench line WLT2 may have the same shape as or a similar shape to that of the second word line WL2.

In embodiments, the plurality of word line trenches WLT may include a plurality of first word line trenches WLT1 and a plurality of second word line trenches WLT2 alternately arranged in the second horizontal direction (the Y direction). In the cell array area MCA and the boundary area BA, the plurality of first word line trenches WLT1 and the plurality of second word line trenches WLT2 may extend in the first horizontal direction (the X direction) to be parallel to each other and may be alternately arranged in the second horizontal direction (the Y direction). In this case, in the boundary area BA, the width of each of the plurality of first word line trenches WLT1 in the second horizontal direction (the Y direction) may be different from the width of each of the plurality of second word line trenches WLT2 in the second horizontal direction (the Y direction).

In embodiments, in the boundary area BA, the plurality of first word line trenches WLT1 may have a shape having a width in the second horizontal direction (the Y direction), which gradually increases away from the cell array area MCA in the first horizontal direction (the X direction). In embodiments, in the boundary area BA, the plurality of second word line trenches WLT2 may have a shape having a width in the second horizontal direction (the Y direction), which gradually decreases away from the cell array area MCA in the first horizontal direction (the X direction).

In embodiments, the first portion WL1a, the second portion WL1b, and the third portion WL1c of each of the plurality of first word lines WL1 may fill each of the plurality of first word line trenches WLT1. Each of the plurality of first word line trenches WLT1 may have substantially the same shape as portions partially or completely filled with the first portion WL1a, the second portion WL1b, and the third portion WL1c of each of the plurality of first word lines WL1.

In embodiments, the first portion WL2a and the second portion WL2b of each of the plurality of second word lines WL2 may fill each of the plurality of second word line trenches WLT2. Each of the plurality of second word line trenches WLT2 may have substantially the same shape as portions partially or completely filled with the first portion WL2a and the second portion WL2b of each of the plurality of second word lines WL2.

Each of the plurality of buried gate structures 120 may include a gate dielectric layer 122, a gate electrode 124, a conductive layer 126, and a capping insulating layer 128. The gate dielectric layer 122 may conformally cover, overlap, or be on the inner wall of each of the plurality of word line trenches WLT (e.g., the bottom surface and the inner surface of each of the plurality of word line trenches WLT). The gate electrode 124 may be on the gate dielectric layer 122 and partially fill each word line trench WLT, the conductive layer 126 may be on the gate electrode 124 and partially fill each word line trench WLT, and the capping insulating layer 128 may cover, overlap, or be on the upper surface of the conductive layer 126 and fill the remaining portion of each word line trench WLT. In embodiments, a plurality of gate electrodes 124 may be at a lower vertical level than the main surface 110M of the substrate 110. In embodiments, each of a plurality of gate dielectric layers 122 may conformally cover, overlap, or be on the inner wall of each word line trench WLT and surround the gate electrode 124, the conductive layer 126, and the capping insulating layer 128. For example, the plurality of gate electrodes 124 may correspond to the plurality of word lines WL shown in FIG. 2.

In embodiments, each of the plurality of gate dielectric layers 122 may include a silicon oxide film, a silicon nitride film, a silicon oxynitride film, an oxide/nitride/oxide (ONO) film, or a high-k dielectric film having a higher dielectric constant than the silicon nitride film. In embodiments, each of the plurality of gate electrodes 124 may include titanium (Ti), titanium nitride (TiN), tantalum (Ta), tantalum nitride (TaN), tungsten (W), tungsten nitride (WN), titanium silicon nitride (TiSiN), tungsten silicon nitride (WSiN), or a combination thereof. In embodiments, each of a plurality of conductive layers 126 may include polysilicon, doped polysilicon, or a combination thereof. In embodiments, each of a plurality of capping insulating layers 128 may include a silicon oxide film, a silicon nitride film, a silicon oxynitride film, or a combination thereof.

In embodiments, at the bottom surface of the word line trench WLT, the vertical level of a portion in contact with the plurality of active areas ACT and the plurality of dummy active areas DACT may be higher than the vertical level of a portion in contact with the device isolation layer 112. The lower surface of the gate electrode 124 may have a concave-convex shape corresponding to a bottom surface profile of the word line trench WLT, and a fin type field-effect transistor (FINFET) structure may be formed on the plurality of active areas ACT and the plurality of dummy active areas DACT.

In embodiments, the word line trench WLT may include a first bottom surface BT1 in contact with each of the plurality of active areas ACT or each of the plurality of dummy active areas DACT and a second bottom surface BT2 in contact with the device isolation layer 112. In embodiments, the first bottom surface BT1 may be at a higher vertical level than the second bottom surface BT2.

In embodiments, the first dummy active area DACT1 selected from among the plurality of dummy active areas DACT may be adjacent to the plurality of active areas ACT, and the second dummy active area DACT2 selected from among the plurality of dummy active areas DACT may be spaced apart from the plurality of active areas ACT in the first horizontal direction (the X direction) with the first dummy active area DACT1 therebetween.

In embodiments, FIG. 3 shows that the outermost active area ACT selected from among the plurality of active areas ACT in the cell array area MCA and most adjacent to the boundary area BA is spaced apart from the boundary structure 114 with three dummy active area DACT therebetween, but the outermost active area ACT is not limited thereto. For example, in the first horizontal direction (the X direction), two or less or four or more dummy active areas DACT may be between the outermost active area ACT and the boundary structure 114.

In embodiments, each of the plurality of gate electrodes 124 may include a center portion 124a in the cell array area MCA and an edge portion 124b in the boundary area BA. In embodiments, the center portion 124a may extend long in the first horizontal direction (the X direction) across the plurality of active areas ACT. In embodiments, the edge portion 124b may extend from the center portion 124a in the first horizontal direction (the X direction) and extend to a portion of the boundary structure 114 across the plurality of dummy active areas DACT. For example, the center portion 124a may vertically overlap the plurality of active areas ACT in the cell array area MCA, and the edge portion 124b may vertically overlap the plurality of dummy active areas DACT and the portion of the boundary structure 114 in the boundary area BA. For example, the edge portion 124b may be in the dummy active area DACT.

In embodiments, a portion of the center portion 124a vertically overlapping the plurality of active areas ACT may have the second width s2 in the second horizontal direction (the Y direction). A portion of the edge portion 124b vertically overlapping the plurality of dummy active areas DACT may have the first width s1 in the second horizontal direction (the Y direction). In embodiments, the width of the edge portion 124b in the second horizontal direction (the Y direction) may be greater than the width of the center portion 124a in the second horizontal direction (the Y direction).

In embodiments, the gate electrode 124 may consecutively extend in the first horizontal direction (the X direction) without disconnection. For example, the gate electrode 124 may not include a disconnected portion in a region in which the edge portion 124b vertically overlaps the plurality of dummy active areas DACT.

In embodiments, the vertical level of the upper surface of the center portion 124a may be substantially the same as the vertical level of the upper surface of the edge portion 124b. For example, the upper surface of the gate electrode 124 may have a flat surface regardless of whether the gate electrode 124 is in the cell array area MCA or the boundary area BA. For example, the upper surface of the gate electrode 124 may have a flat surface in the first horizontal direction (the X direction).

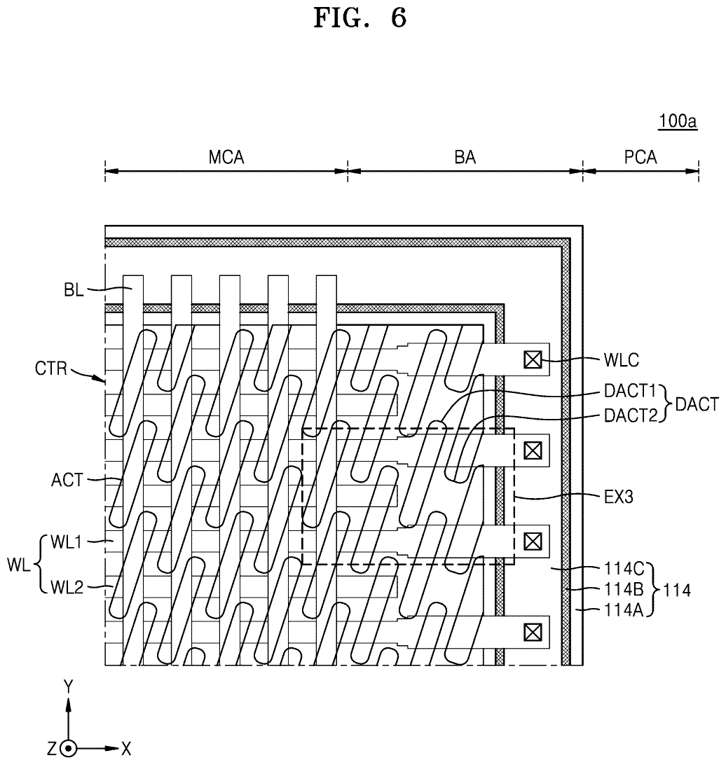

FIG. 6 is a layout diagram illustrating a schematic structure of an integrated circuit device 100a according to embodiments, and illustrates a portion corresponding to FIG. 2.

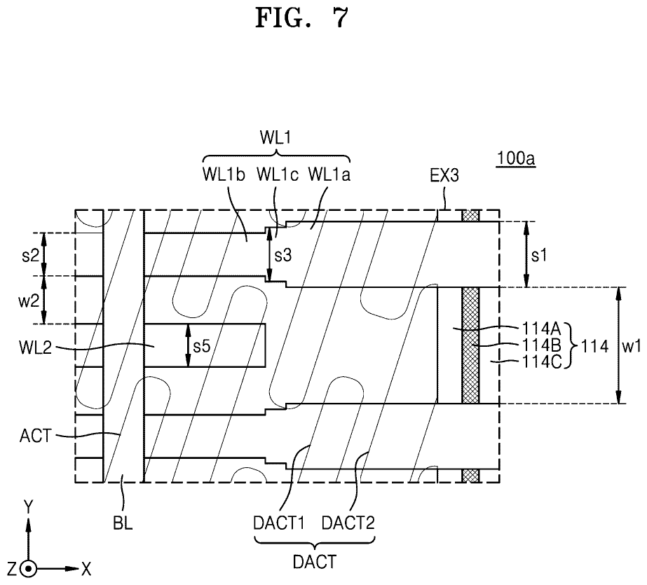

FIG. 7 is an enlarged layout diagram of an area EX3 of FIG. 6.

In describing the integrated circuit device 100a of FIGS. 6 and 7, like reference numerals of the integrated circuit device 100 of FIGS. 1 to 5 denote like elements, and thus their repetitive description will be omitted.

Referring to FIGS. 6 and 7, the plurality of word lines WL may include the plurality of first word lines WL1 and the plurality of second word lines WL2 alternately arranged in the second horizontal direction (the Y direction). In the cell array area MCA and the boundary area BA, the plurality of first word lines WL1 and the plurality of second word lines WL2 may extend in the first horizontal direction (the X direction) to be parallel to each other and may be alternately arranged in the second horizontal direction (the Y direction).

In embodiments, each of the plurality of first word lines WL1 may include the first portion WL1a in the boundary area BA and the second portion WL1b extending from the cell array area MCA to a portion of the boundary area BA and connected to the first portion WL1a. Each of the plurality of second word lines WL2 may include the second portion WL2b extending from the cell array area MCA to a portion of the boundary area BA. In this case, the second portion WL2b of each of the plurality of second word lines WL2 may overlap the second portion WL1b of each of the plurality of first word lines WL1 in the second horizontal direction (the Y direction).

In embodiments, the first portion WL1a of the first word line WL1 may have the first width s1 in the second horizontal direction (the Y direction), and the second portion WL1b of the first word line WL1 may have the second width s2 in the second horizontal direction (the Y direction). In this case, the first width s1 may be greater than the second width s2. For example, the first width s1 may be greater by about 20% than the second width s2 but is not limited thereto.

In embodiments, each of the plurality of first word lines WL1 may further include the third portion WL1c. The third portion WL1c of the first word line WL1 may be between the first portion WL1a of the first word line WL1 and the second portion WL1b of the first word line WL1. In this case, the first portion WL1a, the second portion WL1b, and the third portion WL1c of the first word line WL1 may be consecutively and integrally formed. The third portion WL1c of the first word line WL1 may have the third width s3 in the second horizontal direction (the Y direction). In this case, the third width s3 may be greater than the second width s2 and less than the first width s1. By arranging the third portion WL1c between the first portion WL1a and the second portion WL1b, it may be prevented that the first word line WL1 is cut at the interface between the first portion WL1a and the second portion WL1b due to a necking phenomenon. That is, in the boundary area BA, the plurality of first word lines WL1 may have a shape having a width in the second horizontal direction (the Y direction), which gradually increases away from the cell array area MCA in the first horizontal direction (the X direction). For example, each of the plurality of first word lines WL1 may have a stair shape.

In embodiments, the second portion WL2b of the second word line WL2 may have the fifth width s5 in the second horizontal direction (the Y direction). In this case, the fifth width s5 of the second word line WL2 may be constant. That is, the plurality of second word lines WL2 may have a constant width and extend in the first horizontal direction (the X direction).

In embodiments, the first portion WL1a of the first word line WL1 may be spaced apart by the first distance w1 from the first portion WL2a of the second word line WL2 adjacent to the first word line WL1 in the second horizontal direction (the Y direction). The second portion WL1b of the first word line WL1 may be spaced apart by the second distance w2 from the second portion WL2b of the second word line WL2 adjacent to the first word line WL1 in the second horizontal direction (the Y direction). In this case, the first distance w1 may be greater than the second distance w2.

In embodiments, the plurality of word line contacts WLC may be in contact with some of the plurality of word lines WL in the boundary area BA. Particularly, the plurality of word line contacts WLC may be in contact with the first portions WL1a of the plurality of first word lines WL1 in the vertical direction (the Z direction), respectively.

In embodiments, the integrated circuit device 100a according to the inventive concept may include the first word line WL1 having a width gradually increasing away from the cell array area MCA. Accordingly, a discontinuity failure of a word line WL, which may occur in a processing process, may be prevented, thereby improving the reliability of the integrated circuit device 100. In addition, the width of the first portion WL1a of the first word line WL1 in the second horizontal direction (the Y direction), the first portion WL1a being arranged to overlap the dummy active area DACT in the vertical direction (the Z direction), may increase to prevent disconnection of a word line WL in the boundary area BA in a processing process, thereby improving the reliability of the integrated circuit device 100.

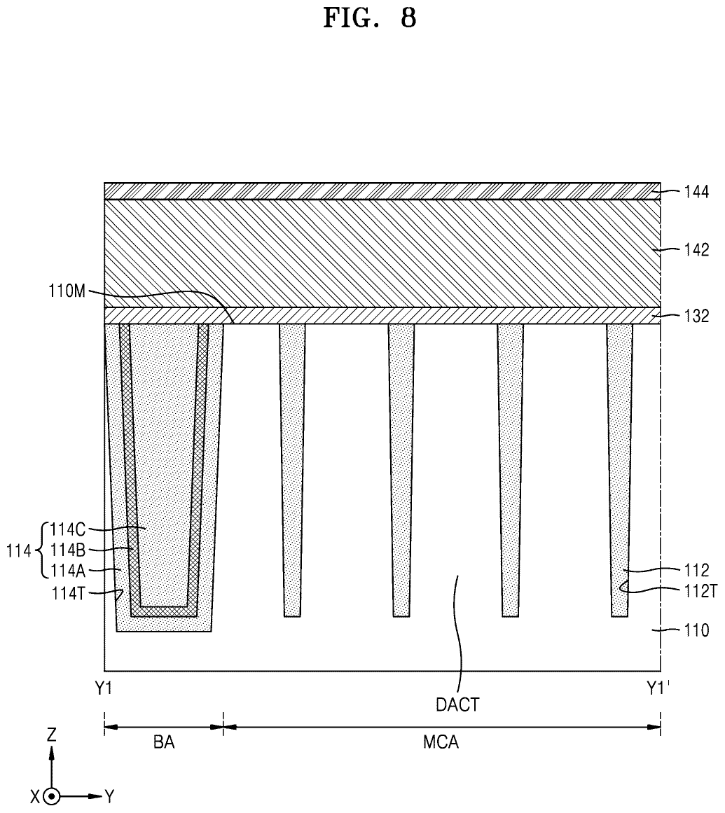

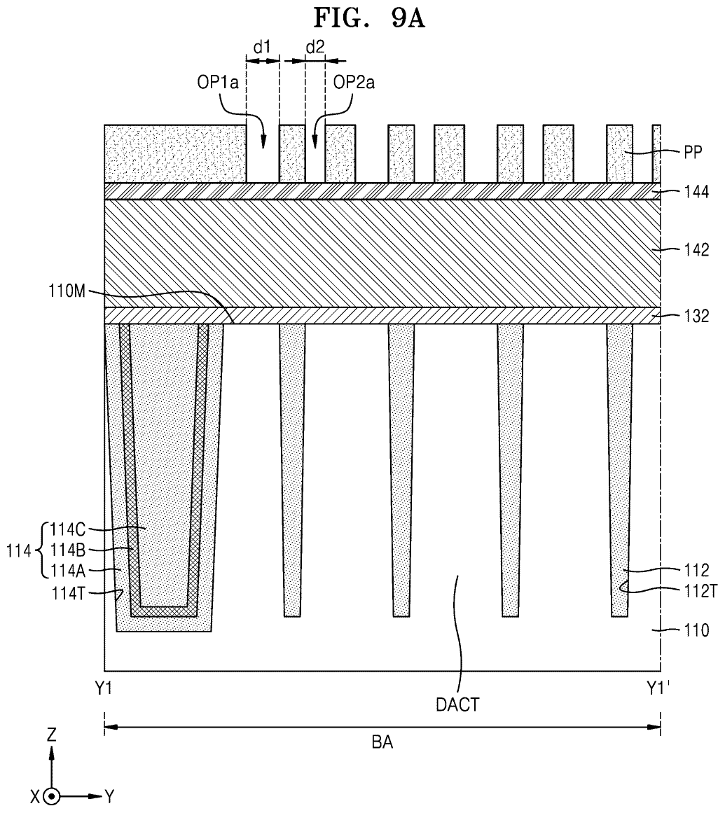

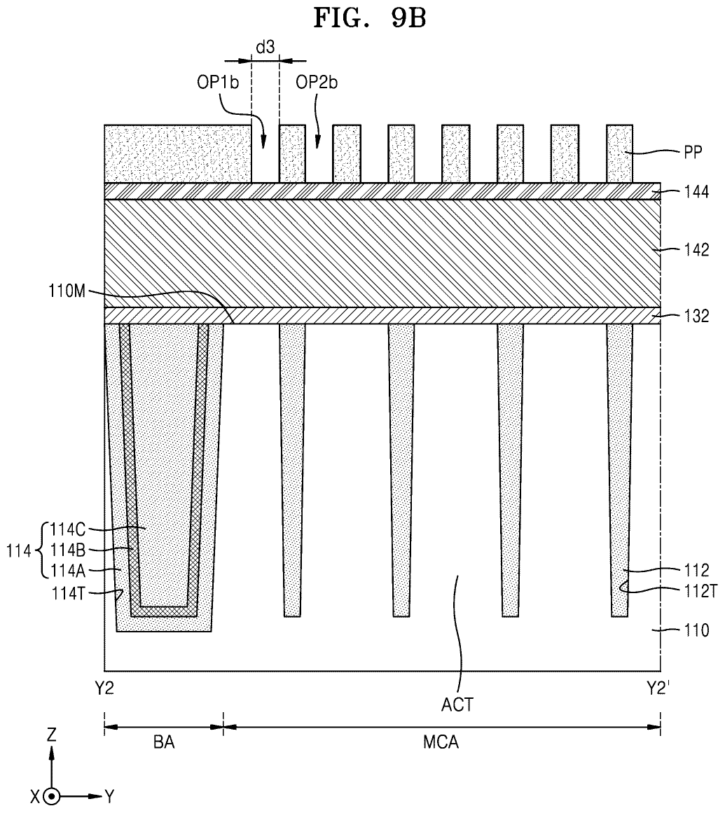

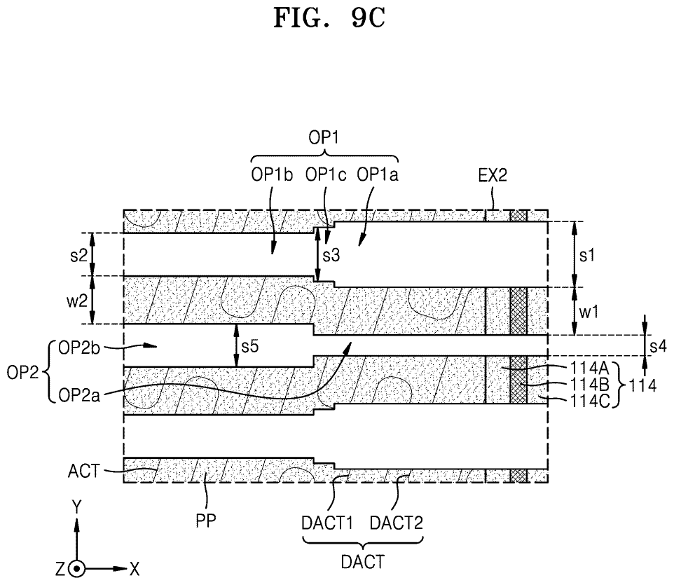

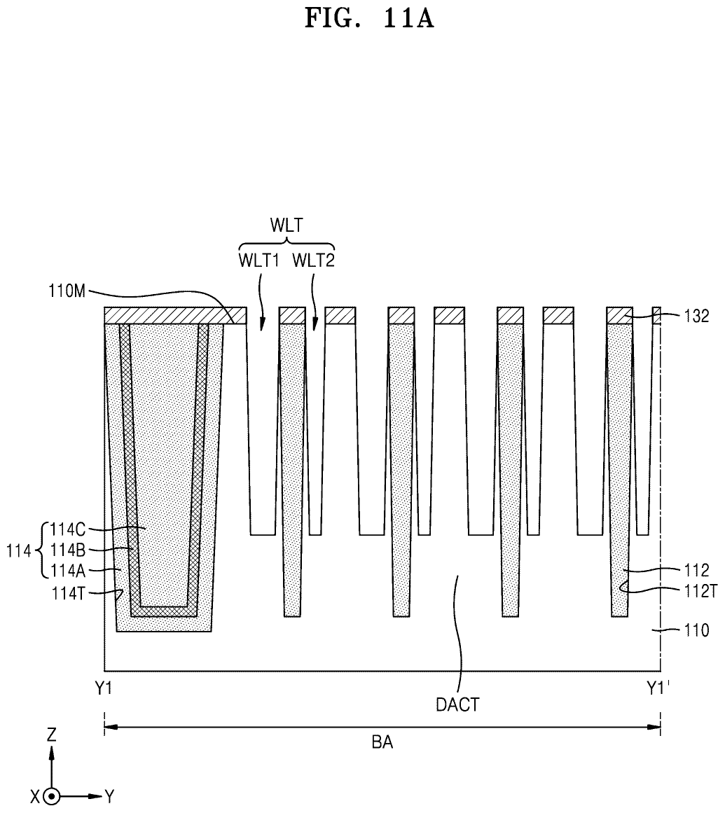

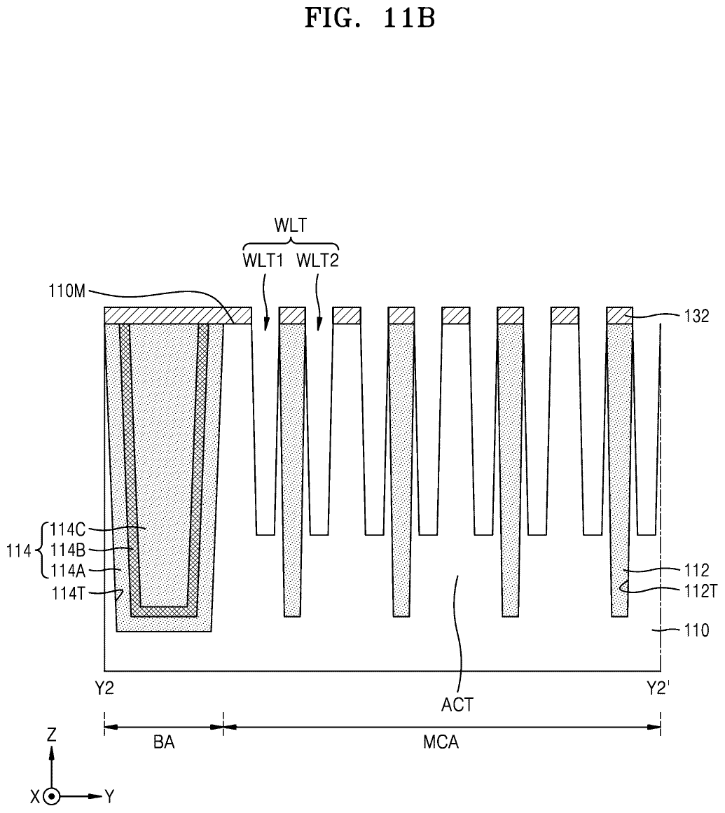

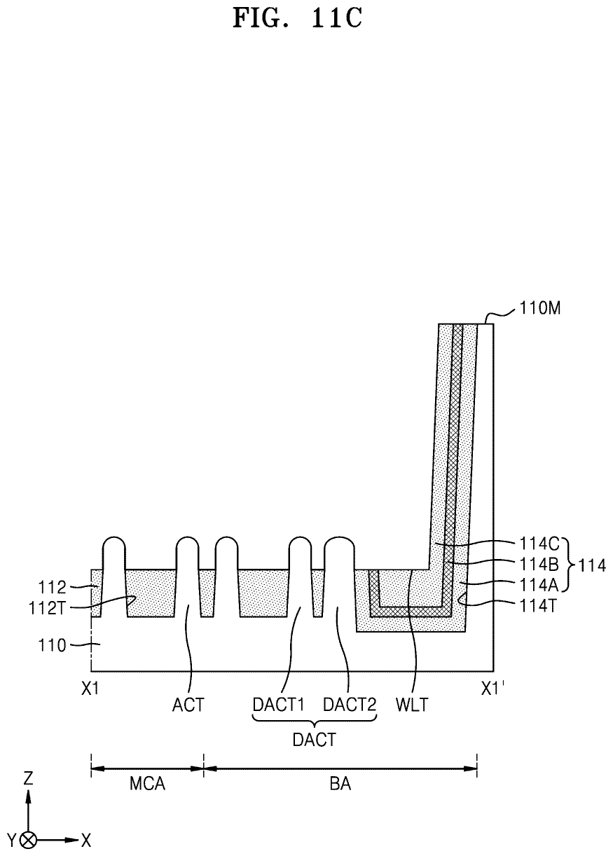

FIGS. 8 to 11C illustrate a method of manufacturing the integrated circuit device 100, according to embodiments, wherein FIGS. 8, 9A, 10A, and 11A are cross-sectional views taken along the line Y1-Y1′ of FIG. 2, FIGS. 9B, 10B, and 11B are cross-sectional views taken along the line Y2-Y2′ of FIG. 2, FIG. 9C is an enlarged layout diagram of the area EX2 of FIG. 2, and FIG. 11C is a cross-sectional view taken along the line X1-X1′ of FIG. 2.

Referring to FIG. 8, the substrate 110, in which the plurality of active areas ACT (see FIG. 4B) and the plurality of dummy active areas DACT are defined by the device isolation layer 112, may be prepared. The substrate 110 may include the boundary structure 114 surrounding the plurality of active areas ACT and the plurality of dummy active areas DACT. In embodiments, a lower protective layer 132, a lower sacrificial layer 142, and an upper sacrificial layer 144 may be sequentially formed on the substrate 110.

In embodiments, the lower protective layer 132 may include at least one material among silicon oxide, silicon nitride, and/or silicon oxynitride. In embodiments, the lower protective layer 132 may be a single layer including silicon oxide. In some embodiments, the lower protective layer 132 may be multiple layers. For example, the lower protective layer 132 may be multiple layers including two or more layers, and each layer that is made of the multiple layers may include any one material selected from among silicon oxide, silicon nitride, and/or silicon oxynitride. In embodiments, the lower protective layer 132 may be formed on the substrate 110 through an atomic layer deposition (ALD) process, a chemical vapor deposition (CVD) process, a plasma enhanced chemical vapor deposition (PECVD) process, a low pressure chemical vapor deposition (LPCVD) process, or the like.

In embodiments, the lower sacrificial layer 142 and the upper sacrificial layer 144 may be sequentially formed on the lower protective layer 132. The lower sacrificial layer 142 and the upper sacrificial layer 144 may have an etching selection ratio with respect to each other.

In embodiments, the lower sacrificial layer 142 may include an amorphous carbon layer (ACL) or a spin-on hardmask (SOH). For example, the SOH may be a carbon based SOH (C-SOH). In embodiments, the lower sacrificial layer 142 may be formed by depositing an ACL on the lower protective layer 132 by an ALD process, a CVD process, a PECVD process, an LPCVD process, or the like. In embodiments, the lower sacrificial layer 142 may be formed of a single layer including an ACL. In some embodiments, the lower sacrificial layer 142 may include carbon-based multiple layers.

In embodiments, the upper sacrificial layer 144 may be a single layer including silicon nitride or silicon oxynitride. For example, the upper sacrificial layer 144 may be formed on the lower sacrificial layer 142 through an ALD process, a CVD process, a PECVD process, an LPCVD process, or the like.

Referring to FIGS. 9A, 9B, and 9C, a photoresist pattern PP may be formed on the upper sacrificial layer 144. The photoresist pattern PP may be formed by coating the upper sacrificial layer 144 with a photoresist composition and then performing exposure and development process thereon. In this case, a process of forming the photoresist pattern PP may use an extreme ultraviolet (EUV) reticle. The EUV reticle may be used to form the photoresist pattern PP extending long in the first horizontal direction (the X direction) across the cell array area MCA and extending to a portion of the boundary area BA. In a plan view, a plurality of first openings OP1 and a plurality of second openings OP2 may have shapes corresponding to the plurality of first word lines WL1 and the plurality of second word lines WL2, respectively.

In embodiments, the photoresist pattern PP may define the plurality of first openings OP1 and the plurality of second openings OP2. The plurality of first openings OP1 and the plurality of second openings OP2 may be alternately arranged in the second horizontal direction (the Y direction). In the cell array area MCA and the boundary area BA, the plurality of first openings OP1 and the plurality of second openings OP2 may extend in the first horizontal direction (the X direction) to be parallel to each other and may be alternately arranged in the second horizontal direction (the Y direction). In this case, in the boundary area BA, the width of each of the plurality of first openings OP1 in the second horizontal direction (the Y direction) may be different from the width of each of the plurality of second openings OP2 in the second horizontal direction (the Y direction).

In embodiments, each of the plurality of first openings OP1 may include a first portion OP1a and a second portion OP1b. Each of the plurality of second openings OP2 may include a first portion OP2a and a second portion OP2b. The first portion OP1a of a first opening OP1 may have the first width s1 in the second horizontal direction (the Y direction), and the first portion OP2a of a second opening OP2 may have the fourth width s4 in the second horizontal direction (the Y direction) as shown in FIG. 9C or width d2 as shown in FIG. 9A. In this case, the first width s1 may be greater than the fourth width s4.

In embodiments, the first portion OP1a of the first opening OP1 may have the first width s1 in the second horizontal direction (the Y direction) as shown in FIG. 9C or width d1 as shown in FIG. 9A, and the second portion OP1b of the first opening OP1 may have the second width s2 in the second horizontal direction (the Y direction) as shown in FIG. 9C or width d3 as shown in FIG. 9B. In this case, the first width s1 may be greater than the second width s2. For example, the first width s1 may be greater by about 20% than the second width s2 but is not limited thereto.

In embodiments, each of the plurality of first openings OP1 may further include a third portion OP1c. The third portion OP1c of the first opening OP1 may be between the first portion OP1a of the first opening OP1 and the second portion OP1b of the first opening OP1. In this case, the first portion OP1a, the second portion OP1b, and the third portion OP1c of the first opening OP1 may be consecutively and integrally formed. The third portion OP1c of the first opening OP1 may have the third width s3 in the second horizontal direction (the Y direction). In this case, the third width s3 may be greater than the second width s2 and less than the first width s1. That is, in the boundary area BA, the plurality of first openings OP1 may have a shape having a width in the second horizontal direction (the Y direction), which gradually increases away from the cell array area MCA in the first horizontal direction (the X direction). Unlike forming a photoresist pattern through a quadruple patterning technology (QPT) process or the like according to a comparative example, the photoresist pattern PP may be formed using an EUV reticle in the method of manufacturing the integrated circuit device 100 according to the inventive concept, thereby forming the first opening OP1 having a gradually increasing width and a stair shape.

In embodiments, the first portion OP2a of the second opening OP2 may have the fourth width s4 in the second horizontal direction (the Y direction), and the second portion OP2b of the second opening OP2 may have the fifth width s5 in the second horizontal direction (the Y direction). In this case, the fourth width s4 may be less than the fifth width s5. For example, the fourth width s4 may be less by about 20% than the fifth width s5 but is not limited thereto.

In embodiments, the distance between the first opening OP1 and the second opening OP2 adjacent to each other in the second horizontal direction (the Y direction) may be constant. The first portion OP1a of the first opening OP1 may be spaced apart by the first distance w1 from the first portion OP2a of the second opening OP2 adjacent to the first opening OP1 in the second horizontal direction (the Y direction). The second portion OP1b of the first opening OP1 may be spaced apart by the second distance w2 from the second portion OP2b of the second opening OP2 adjacent to the first opening OP1 in the second horizontal direction (the Y direction). In this case, the first distance w1 may be the same as the second distance w2. That is, in the boundary area BA and the cell array area MCA, the width of the photoresist pattern PP in the second horizontal direction (the Y direction) may be constant.

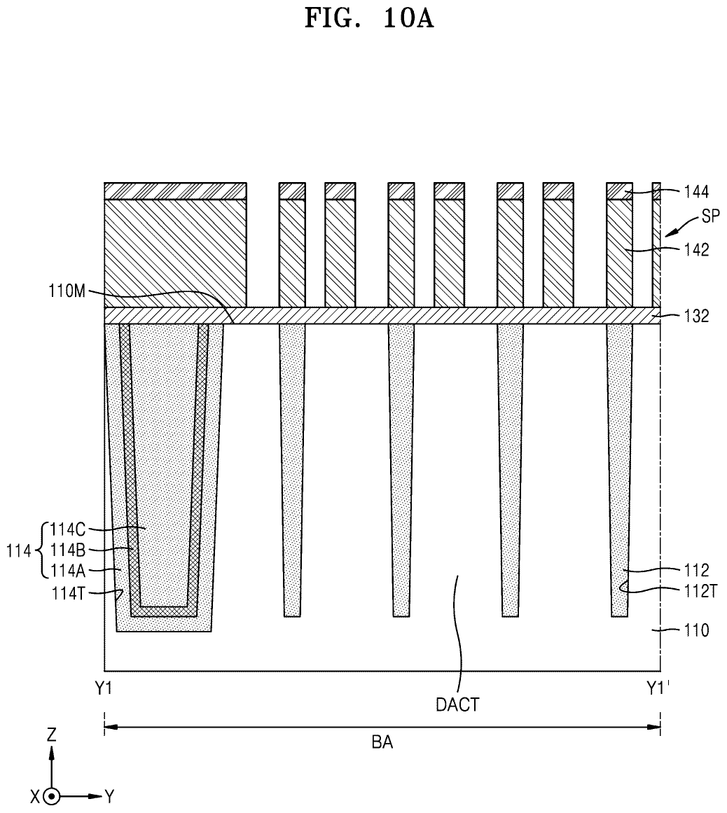

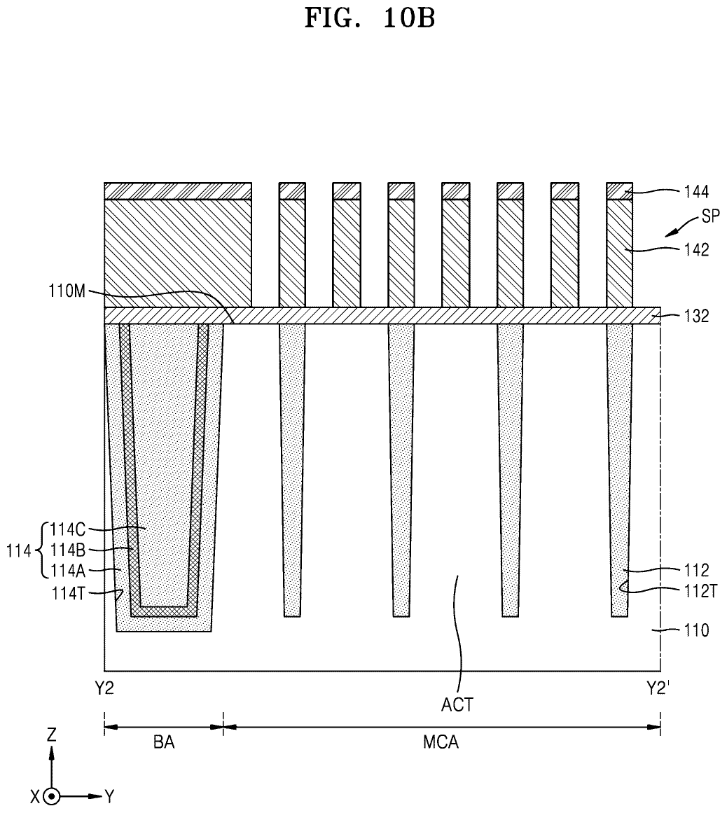

Referring to FIGS. 10A and 10B, the photoresist pattern PP (see FIGS. 9A and 9B) may be used as an etching mask to remove portions of the upper sacrificial layer 144 and the lower sacrificial layer 142, thereby forming a sacrificial pattern SP. In a process of forming the sacrificial pattern SP, the photoresist pattern PP (see FIGS. 9A and 9B) remaining on the upper sacrificial layer 144 may also be removed.

In embodiments, the sacrificial pattern SP may consist of the lower sacrificial layer 142 and the upper sacrificial layer 144 remaining after being removed in an etching process. In embodiments, the upper surface of the lower protective layer 132 may be partially exposed through openings defined by the sacrificial pattern SP.

Referring to FIGS. 11A, 11B, and 11C, the sacrificial pattern SP (see FIGS. 10A and 10B) may be used as an etching mask to remove portions of the lower protective layer 132 and the substrate 110, thereby forming the plurality of word line trenches WLT.

In embodiments, the first word trench line WLT1 may be formed at a portion of the substrate 110 vertically overlapping the first opening OP1 (see FIGS. 9A, 9B, and 9C), and the second word trench line WLT2 may be formed at a portion of the substrate 110 vertically overlapping the second opening OP2 (see FIGS. 9A, 9B, and 9C). In embodiments, in a process of forming the word line trench WLT, the sacrificial pattern SP (see FIGS. 10A and 10B) may be removed.

Referring back to FIGS. 3, 4A, and 4B, after removing the remaining lower protective layer 132, the gate dielectric layer 122, the gate electrode 124, the conductive layer 126, and the capping insulating layer 128 may be sequentially formed inside each of the plurality of word line trenches WLT, and the main surface 110M of the substrate 110 may be exposed through a planarization process. Thereafter, a direct contact (not shown) and a bit line BL (see FIG. 2) connected to the direct contact (not shown) may be formed on the plurality of active areas ACT, and a capacitor structure (not shown) on the bit line BL and connected to the plurality of active areas ACT via a contact structure (not shown) may be formed.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, “third”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure. Further, as used herein, the term “and/or” includes any and all combinations of one or more of the associated listed items.

While the inventive concept has been particularly shown and described with reference to embodiments thereof, it will be understood that various changes in form and details may be made therein without departing from the spirit and scope of the following claims.

What is claimed is:

1. An integrated circuit device comprising:
a substrate comprising a cell array area including a plurality of active areas and a boundary area including a plurality of dummy active areas and adjacent the cell array area;
a plurality of word lines extending in a first horizontal direction and alternately arranged in a second horizontal direction, wherein the plurality of word lines extend in the cell array area and the boundary area; and
a plurality of word line contacts in contact with respective ones of the plurality of word lines in the boundary area,
wherein the plurality of word lines comprise a plurality of first word lines and a plurality of second word lines alternately arranged in the second horizontal direction, wherein a width of each of the plurality of first word lines in the second horizontal direction differs from a width of each of the plurality of second word lines in the second horizontal direction.

2. The integrated circuit device of claim 1, wherein each of the plurality of word lines comprises:
a first portion in the boundary area; and
a second portion extending from the cell array area to a portion of the boundary area and integral with the first portion,
wherein a width of the first portion in the second horizontal direction differs from a width of the second portion in the second horizontal direction.

3. The integrated circuit device of claim 2, wherein the first portion of each of the plurality of first word lines has a first width in the second horizontal direction, the second portion of each of the plurality of first word lines has a second width in the second horizontal direction, and the first width is greater than the second width.

4. The integrated circuit device of claim 3, wherein each of the plurality of first word lines further comprises a third portion between the first portion and the second portion and having a third width in the second horizontal direction, and
wherein the third width is greater than the second width and is less than the first width.

5. The integrated circuit device of claim 2, wherein the first portion of each of the plurality of second word lines has a fourth width in the second horizontal direction, the second portion of each of the plurality of second word lines has a fifth width in the second horizontal direction, and
wherein the fourth width is less than the fifth width.

6. The integrated circuit device of claim 2, wherein a distance in the second horizontal direction between the first portion of each of the plurality of first word lines and the first portion of each of the plurality of second word lines adjacent to a first word line of the plurality of first word lines in the second horizontal direction is same as a distance in the second horizontal direction between the second portion of the first word line of the plurality of first word lines and the second portion of a second word line of the plurality of second word lines adjacent to the first word line of the plurality of first word lines in the second horizontal direction.

7. The integrated circuit device of claim 2, wherein the first portion of each of the plurality of first word lines has a first width in the second horizontal direction, the first portion of each of the plurality of second word lines has a fourth width in the second horizontal direction, and
wherein the first width is greater than the fourth width.

8. The integrated circuit device of claim 7, wherein the plurality of word line contacts are in contact with the first portions of respective ones of the plurality of first word lines in a vertical direction that is perpendicular to the first horizontal direction and the second horizontal direction, respectively.

9. The integrated circuit device of claim 3, wherein each of the plurality of dummy active areas comprises:
a first dummy active area adjacent to the plurality of active areas; and
a second dummy active area spaced apart from the plurality of active areas with the first dummy active area therebetween in the first horizontal direction and having an area greater than the first dummy active area.

10. The integrated circuit device of claim 9, wherein the first portion of each of the plurality of first word lines overlaps the second dummy active area in a vertical direction that is perpendicular to the first horizontal direction and the second horizontal direction.

11. An integrated circuit device comprising:
a substrate comprising a cell array area including a plurality of active areas and a boundary area including a plurality of dummy active areas and adjacent the cell array area;
a plurality of word lines extending in a first horizontal direction and alternately arranged in a second horizontal direction, wherein the plurality of word lines extend in the cell array area and the boundary area; and
a plurality of word line contacts in contact with respective ones of the plurality of word lines in the boundary area,
wherein the plurality of word lines comprise:
a plurality of first word lines having a width gradually increasing in the second horizontal direction away from the cell array area extending into the boundary area; and
a plurality of second word lines alternately arranged with the plurality of first word lines in the second horizontal direction and having a constant width in the second horizontal direction.

12. The integrated circuit device of claim 11, wherein each of the plurality of first word lines comprises a first portion in the boundary area and a second portion extending from the cell array area to a portion of the boundary area and integral with the first portion, and
wherein the plurality of second word lines extend from the cell array area to a portion of the boundary area to overlap the second portions of the plurality of first word lines in the second horizontal direction, respectively.

13. The integrated circuit device of claim 12, wherein the first portion of each of the plurality of first word lines has a first width in the second horizontal direction, the second portion of each of the plurality of first word lines has a second width in the second horizontal direction, and the first width is greater than the second width.

14. The integrated circuit device of claim 13, wherein each of the plurality of first word lines further comprises a third portion between the first portion and the second portion and having a third width in the second horizontal direction, and
wherein the third width is greater than the second width and is less than the first width.

15. The integrated circuit device of claim 11, wherein the plurality of word line contacts are in contact with respective ones of the plurality of first word lines in a vertical direction that is perpendicular to the first horizontal direction and the second horizontal direction, respectively.

16. The integrated circuit device of claim 13, wherein each of the plurality of dummy active areas comprises:
a first dummy active area adjacent to the plurality of active areas; and
a second dummy active area spaced apart from the plurality of active areas with the first dummy active area therebetween in the first horizontal direction and having an area greater than the first dummy active area.

17. The integrated circuit device of claim 16, wherein the first portion of each of the plurality of first word lines overlaps the second dummy active area in a vertical direction that is perpendicular to the first horizontal direction and the second horizontal direction.

18. An integrated circuit device comprising:
a substrate comprising a cell array area including a plurality of active areas and a boundary area including a plurality of dummy active areas and adjacent the cell array area;
a plurality of word lines including a plurality of first word lines and a plurality of second word lines extending in a first horizontal direction and alternately arranged in a second horizontal direction, wherein the plurality of word lines extend in the cell array area and the boundary area; and
a plurality of word line contacts in contact with respective ones of the plurality of first word lines in a vertical direction in the boundary area,
wherein each of the plurality of first word lines includes a first portion in the boundary area, a second portion extending from the cell array area into the boundary area, and a third portion between the first portion and the second portion, each of the plurality of second word lines includes a fourth portion in the boundary area and a fifth portion extending from the cell array area into the boundary area and in contact with the fourth portion,
wherein a first width of the first portion of each of the plurality of first word lines in the second horizontal direction is greater than a second width of the second portion of a first word line of the plurality of first word lines in the second horizontal direction, and
wherein a fourth width of the fourth portion of each of the plurality of second word lines in the second horizontal direction is less than a fifth width of the fifth portion of a second word line of the plurality of second word lines in the second horizontal direction.

19. The integrated circuit device of claim 18, wherein the third portion has a third width in the second horizontal direction, and the third width is greater than the second width and is less than the first width.

20. The integrated circuit device of claim 18, wherein a distance in the second horizontal direction between the first portion of each of the plurality of first word lines and the fourth portion of each of the plurality of second word lines adjacent to a first word line of the plurality of first word lines in the second horizontal direction is same as a distance in the second horizontal direction between the second portion of the first word line of the plurality of first word lines and the fifth portion of a second word line of the plurality of second word lines adjacent to the first word line of the plurality of first word lines in the second horizontal direction.
